(19) United States
(12) Patent Application Publication
(10) Pub. No.: US 2026/0303421 A1
(43) Pub. Date: Oct. 1, 2026

(54) VOLTAGE SWITCHING IN A POWER MANAGEMENT INTEGRATED CIRCUIT

(71) Applicant: Qorvo US, Inc., Greensboro, NC (US)

(72) Inventors: Robert Moehrke, Winston-Salem, NC (US); Nadim Khlat, Ceret (FR); Michael R. Kay, Summerfield, NC (US)

(21) Appl. No.: 19/168,911

(22) PCT Filed: Mar. 20, 2024
(86) PCT No.: PCT/US2024/020693

§ 371 Date: Sep. 25, 2025

Related U.S. Application Data
(60) Provisional application No. 63/456,661, filed on Apr. 3, 2023.

(51) Int. Cl. H04L 27/12; H03F 1/02; H03F 3/19; H03F 3/24

(52) U.S. Cl. CPC H04L 27/122; H03F 1/02; H03F 3/19; H03F 3/24

(57) ABSTRACT

Voltage switching in a power management integrated circuit (PMIC) is provided. Herein, the PMIC is required to change a voltage from a present level in a present time interval to a future level in an upcoming time interval with a very short switching interval (e.g., <2 microseconds). As such, the PMIC is configured to determine a voltage transition scheme based at least on the present level and the future level of the voltage. By determining and employing an appropriate voltage transition scheme, the PMIC can change the voltage from the present level to the future level in a timely manner.

### RELATED APPLICATIONS

This application claims the benefit of U.S. provisional patent application Ser. No. 63/456,661, filed on Apr. 3, 2023, the disclosure of which is hereby incorporated herein by reference in its entirety.

### FIELD OF THE DISCLOSURE

The technology of the disclosure relates generally to a power management integrated circuit (PMIC).

### BACKGROUND

Fifth generation (5G) new radio (NR) (5G-NR) has been widely regarded as the next generation of wireless communication technology beyond the current third generation (3G) and fourth generation (4G) technologies. In this regard, a wireless communication device capable of supporting the 5G-NR wireless communication technology is expected to achieve higher data rates, improved coverage range, enhanced signaling efficiency, and reduced latency.

Downlink and uplink transmissions in a 5G-NR system are widely based on orthogonal frequency division multiplexing (OFDM) technology. In an OFDM based system, physical radio resources are divided into a number of subcarriers in a frequency domain and a number of OFDM symbols in a time domain. The subcarriers are orthogonally separated from each other by a subcarrier spacing (SCS). The OFDM symbols are separated from each other by a cyclic prefix (CP), which acts as a guard band to help overcome inter-symbol interference (ISI) between the OFDM symbols.

A radio frequency (RF) signal communicated in the OFDM based system is often modulated into multiple subcarriers in the frequency domain and multiple OFDM symbols in the time domain. The multiple subcarriers occupied by the RF signal collectively define a modulation bandwidth of the RF signal. The multiple OFDM symbols, on the other hand, define multiple time intervals during which the RF signal is communicated. In the 5G-NR system, the RF signal is typically modulated with a high modulation bandwidth in excess of 200 MHz.

The duration of an OFDM symbol depends on the SCS and the modulation bandwidth. The table below (Table 1) provides some OFDM symbol durations, as defined by 3G partnership project (3GPP) standards for various SCSs and modulation bandwidths. Notably, the higher the modulation bandwidth is, the shorter the OFDM symbol duration will be. For example, when the SCS is 120 KHz and the modulation bandwidth is 400 MHz, the OFDM symbol duration is 8.93 μs.

TABLE 1

| | | | | OFDM | |
|---|---|---|---|---|---|
| | Slot | # of Slots | | Symbol | Modulation |
| SCS | Length | per | CP | Duration | Bandwidth |
| (KHz) | (μs) | Subframe | (μs) | (μs) | (MHz) |
| 15 | 1000 | 1 | 4.69 | 71.43 | 50 |
| 30 | 500 | 2 | 2.34 | 35.71 | 100 |
| 60 | 250 | 4 | 1.17 | 17.86 | 200 |
| 120 | 125 | 8 | 0.59 | 8.93 | 400 |

In a 5G-NR system, the RF signal can be modulated with a time-variant power that changes from one OFDM symbol to another. In this regard, a power amplifier circuit(s) is required to amplify the RF signal to a certain power level within each OFDM symbol duration. Such inter-symbol power variation creates a unique challenge for a power management integrated circuit (PMIC) because the PMIC must be able to adapt a voltage supplied to the power amplifier circuit within the CP of each OFDM symbol to help avoid distortion (e.g., amplitude clipping) in the RF signal.

### SUMMARY

Embodiments of the disclosure relate to voltage switching in a power management integrated circuit (PMIC). Herein, the PMIC is required to change a voltage from a present level in a present time interval to a future level in an upcoming time interval with a very short switching interval (e.g., <2 microseconds). As such, the PMIC is configured to determine a voltage transition scheme based at least on the present level and the future level of the voltage. By determining and employing an appropriate voltage transition scheme, the PMIC can change the voltage from the present level to the future level in a timely manner.

In one aspect, a PMIC is provided. The PMIC includes a voltage processing circuit. The voltage processing circuit is configured to generate a voltage in each of multiple time intervals for amplifying a radio frequency (RF) signal. The PMIC also includes a control circuit. The control circuit is configured to receive a target voltage indicating a future level of the voltage in an upcoming time interval among the multiple time intervals. The control circuit is also configured to determine a present level of the voltage in a present time interval immediately preceding the upcoming time interval among the multiple time intervals. The control circuit is also configured to select a voltage transition scheme based at least on the present level of the voltage, the future level of the voltage, and a threshold voltage. The control circuit is also configured to control the voltage processing circuit to transition the voltage from the present level to the future level based on the selected voltage transition scheme.

In another aspect, a method for switching a voltage in a PMIC is provided. The method includes receiving a target voltage indicating a future level of the voltage in an upcoming time interval among multiple time intervals. The method also includes determining a present level of the voltage in a present time interval immediately preceding the upcoming time interval among the multiple time intervals. The method also includes selecting a voltage transition scheme based at least on the present level of the voltage, the future level of the voltage, and a threshold voltage. The method also includes transitioning the voltage from the present level to the future level based on the selected voltage transition scheme.

In another aspect, a wireless device is provided. The wireless device includes a PMIC. The PMIC includes a voltage processing circuit. The voltage processing circuit is configured to generate a voltage in each of multiple time intervals for amplifying a radio frequency (RF) signal. The PMIC also includes a control circuit. The control circuit is configured to receive a target voltage indicating a future level of the voltage in an upcoming time interval among the multiple time intervals. The control circuit is also configured to determine a present level of the voltage in a present time interval immediately preceding the upcoming time interval among the multiple time intervals. The control circuit is also configured to select a voltage transition scheme based at least on the present level of the voltage, the future level of the voltage, and a threshold voltage. The control circuit is also configured to control the voltage processing circuit to transition the voltage from the present level to the future level based on the selected voltage transition scheme.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a schematic diagram of an exemplary wireless communication circuit wherein a power management integrated circuit (PMIC) is configured according to embodiments of the present disclosure to change a voltage based on a selected voltage transition scheme;

FIG. 2 is a flowchart of an exemplary process whereby the PMIC in FIG. 1 can determine the selected voltage transition scheme;

FIG. 3 is a schematic diagram of a control circuit in the PMIC in FIG. 1;

FIG. 4 is a schematic diagram of an exemplary communication device wherein the wireless communication circuit of FIG. 1 can be provided; and

FIG. 5 is a flowchart of an exemplary process for switching the voltage in the PMIC in FIG. 1.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the disclosure relate to voltage switching in a power management integrated circuit (PMIC). Herein, the PMIC is required to change a voltage from a present level in a present time interval to a future level in an upcoming time interval with a very short switching interval (e.g., <2 microseconds). As such, the PMIC is configured to determine a voltage transition scheme based at least on the present level and the future level of the voltage. By determining and employing an appropriate voltage transition scheme, the PMIC can change voltage from the present level to the future level in a timely manner.

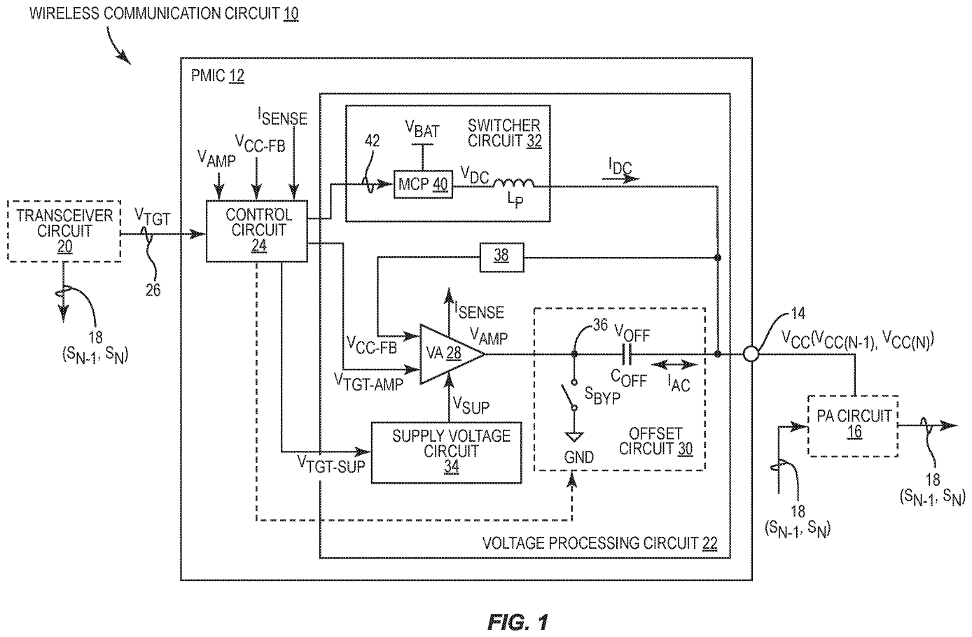

FIG. 1 is a schematic diagram of an exemplary wireless communication circuit 10 wherein a PMIC 12 is configured according to embodiments of the present disclosure to change a voltage V_{CC} based on a voltage transition scheme selected among a first voltage transition scheme and a second voltage transition scheme. The PMIC 12 includes a voltage output 14 that outputs the voltage V_{CC} to a power amplifier circuit 16, which is configured to amplify a radio frequency (RF) signal 18 based on the voltage V_{CC}.

The RF signal 18, which may be generated by a transceiver circuit 20, is modulated in multiple time intervals. For the sake of reference and illustration, the time intervals are represented hereinafter by a pair of adjacent time intervals S_{N-1}, S_{N}, wherein S_{N} immediately succeeds S_{N-1}. Understandably, the RF signal 18 can be modulated in an infinite number of continuous time intervals. Hereinafter, the time interval S_{N-1} is referred to interchangeably as a present time interval S_{N-1} and the time interval S_{N} is referred interchangeably as an upcoming time interval S_{N}.

In the context of the present disclosure, each of the time intervals S_{N-1}, S_{N} can have a duration of an orthogonal frequency division multiplexing (OFDM) symbol. In this regard, each of the time intervals S_{N-1}, S_{N} has a respective cyclic prefix (CP) that corresponds to a respective sub-carrier spacing (SCS), as shown above in Table 1. Understandably, each of the time intervals S_{N-1}, S_{N} can be modulated to carry a data payload and/or a reference signal, such as a demodulation reference signal (DMRS) and a sounding reference signal (SRS).

The PMIC 12 includes a voltage processing circuit 22 that is coupled to the voltage output 14. The voltage processing circuit 22 is configured to generate the voltage V_{CC} at a respective level in each of the time intervals S_{N-1}, S_{N}. Given that the power amplifier circuit 16 needs to amplify the data symbols and the reference symbols to different power levels, the voltage processing circuit 22 needs to adapt (increase or decrease) the voltage V_{CC} on a per-symbol basis. Moreover, the voltage processing circuit 22 must change the voltage V_{CC} from a present level of the voltage V_{CC} (denoted as “V_{CC(N-1)}”) in the present time interval S_{N-1} to a future level of the voltage V_{CC} (denoted as “V_{CC(N)}”) in the upcoming time interval S_{N} within the respective CP of the upcoming time interval S_{N}.

In this regard, the PMIC 12 is configured to further include a control circuit 24. The control circuit 24 is configured to dynamically determine whether to change the voltage V_{CC} based on the first voltage transition scheme or the second voltage transition scheme. As described in detail below, either one of the voltage transition schemes allows the PMIC 12 to adapt the voltage V_{CC} from the present level V_{CC(N-1)} to the future level V_{CC(N)} within a defined voltage transition interval. Herein, the defined voltage transition interval can be two microseconds (2 μs) or a duration of the respective CP in the upcoming time interval S_{N}, whichever is shorter.

In an embodiment, the control circuit 24 is configured to receive a target voltage V_{TGT} from the transceiver circuit 20. In a non-limiting example, the control circuit 24 can receive the voltage V_{TGT} via an RF frontend (RFFE) bus 26. Specifically, the target voltage V_{TGT} provides an indication as to how the voltage V_{CC} will transition (increase, decrease, or remain unchanged) from the present level V_{CC(N-1)} in the present time interval S_{N-1} to the future level V_{CC(N)} in the upcoming time interval S_{N}. In an embodiment, the transceiver circuit 20 may also indicate an end of the present time interval S_{N-1} and/or a start of the upcoming time interval S_{N}. In an alternative embodiment, the control circuit 24 may determine the end of the present time interval S_{N-1} and/or the start of the upcoming time interval S_{N} based on an internal clock and/or information (e.g., SCS) prestored in the control circuit 24.

Accordingly, the control circuit 24 can select one of the first voltage transition scheme and the second voltage transition scheme and control the voltage processing circuit 22 to transition the voltage V_{CC} from the present level V_{CC(N-1)} to the future level V_{CC(N)} based on the selected voltage transition scheme.

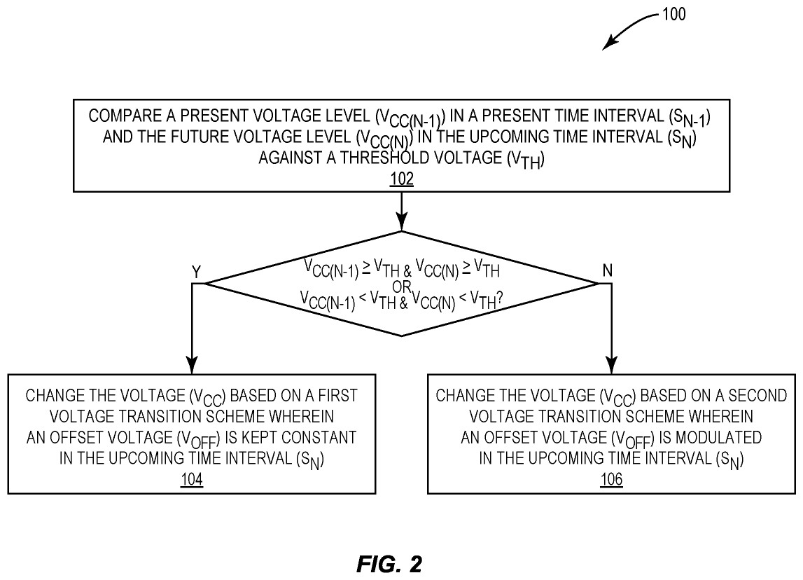

In an embodiment, the control circuit 24 can determine whether the voltage V_{CC} should be changed according to the first voltage transition scheme, or the second voltage transition scheme based on a process. In this regard, FIG. 2 is a flowchart of an exemplary process 100 whereby the PMIC 12 in FIG. 1 can determine whether to change the voltage V_{CC} based on the first voltage transition scheme or the second voltage transition scheme.

Herein, the control circuit 24 compares both the present level V_{CC(N-1)} in the present time interval S_{N-1} and the future level V_{CC(N)} in the upcoming time interval S_{N} against a threshold voltage V_{TH} (step 102). If the present level V_{CC(N-1)} and the future level V_{CC(N)} are both higher than or equal to the threshold voltage V_{TH} (V_{CC(N-1)}>V_{TH} and V_{CC(N)}>V_{TH}), or if the present level V_{CC(N-1)} and the future level V_{CC(N)} are both lower than the threshold voltage V_{TH} (V_{CC(N-1)}<V_{TH} and V_{CC(N)}<V_{TH}), the control circuit 24 will change the voltage V_{CC} based on the first voltage transition scheme (step 104). Otherwise, the control circuit 24 will change the voltage V_{CC} based on the second voltage transition scheme (step 106). Notably, both the first voltage transition scheme and the second voltage transition scheme are so determined to ensure that the PMIC 12 can change the modulated voltage V_{CC} from the present voltage level V_{CC(N-1)} to the future voltage level V_{CC(N)} within a very short switching interval (e.g., <20 nanoseconds).

With reference back to FIG. 1, the voltage processing circuit 22 includes a voltage amplifier 28 (denoted as “VA”), an offset circuit 30, a switcher circuit 32, and a supply voltage circuit 34. The voltage amplifier 28 is coupled to an input 36 of the offset circuit 30 and the offset circuit 30 is coupled to the voltage output 14. In the context of the present disclosure, the power amplifier circuit 16 is assumed to have a much higher bandwidth than that of the offset circuit 30.

Specifically, the voltage amplifier 28 is configured to generate an initial voltage V_{AMP} based on an amplifier target voltage V_{TGT-AMP} and a supply voltage V_{SUP}. The supply voltage circuit 34 is configured to generate the supply voltage V_{SUP} based on a supply target voltage V_{TGT-SUP} and provide the supply voltage V_{SUP} to the voltage amplifier 28.

The offset circuit 30 includes an offset capacitor C_{OFF} and a bypass switch S_{BYP}. The offset capacitor C_{OFF} is coupled between the input 36 and the voltage output 14, and the bypass switch S_{BYP} is coupled between the input 36 and a ground (GND). The offset capacitor C_{OFF} may be charged or discharged to provide an offset voltage V_{OFF} between the voltage amplifier 28 and the voltage output 14. As a result, the offset circuit 30 can raise the initial voltage V_{AMP} by the offset voltage V_{OFF} to thereby generate the voltage V_{CC} at the voltage output 14 (V_{CC}=V_{AMP}+V_{OFF}). The voltage processing circuit 22 further includes a feedback loop 38, which is configured to provide a feedback of the voltage V_{CC} (denoted as “V_{CC-FB}”) at the voltage output 14 to the voltage amplifier 28.

Under the first voltage transition scheme, the control circuit 24 is configured to cause the offset voltage V_{OFF} to be kept constant in the upcoming time interval S_{N}. Understandably, by keeping the offset voltage V_{OFF} constant, it is not necessary to charge or discharge the offset capacitor C_{OFF}. As a result, it is possible to prevent potential power loss resulting from charging or discharging the offset capacitor C_{OFF}.

Alternatively, under the second voltage transition scheme, the control circuit 24 is configured to cause the offset voltage V_{OFF} to be modulated in the upcoming time interval S_{N}. For an in-depth description as to how the control circuit 24 maintains the offset voltage V_{OFF} under the first voltage transition scheme or modulates the offset voltage V_{OFF} under the second voltage transition scheme, please refer to International Patent Application Number PCT/US2023/027865, entitled “VOLTAGE SWITCHING IN A POWER MANAGEMENT INTEGRATED CIRCUIT.”

The switcher circuit 32 includes a multi-level charge pump (MCP) 40. The MCP 40, which may be a direct current (DC)-DC buck-boost converter, is configured to generate a low-frequency voltage V_{DC} (e.g., DC voltage) based on a battery voltage V_{BAT}. Specifically, the MCP 40 may operate in a buck mode to generate the low-frequency voltage V_{DC} at 0×V_{BAT} or 1×V_{BAT}, or in a boost mode to generate the low-frequency voltage V_{DC} at 2×V_{BAT}. The MCP 40 may be configured to toggle between the buck mode and the boost mode based on a duty cycle signal 42 (e.g., 20%@0×V_{BAT}, 30%@1×V_{BAT}, and 50%@2×V_{BAT}). Accordingly, the MCP 40 may be controlled by the duty cycle signal 42 to generate the low-frequency voltage V_{DC} at any desired level.

The switcher circuit 32 also includes a power inductor L_{P} coupled in series to the MCP 40. The power inductor L_{P} is configured to induce a low-frequency current I_{DC} (e.g., a DC current) based on the low-frequency voltage V_{DC}. Given that the duty cycle signal 42 can directly control the low-frequency voltage V_{DC}, the duty cycle signal 42 can likewise cause the low-frequency current I_{DC} to be generated at any desired amount.

As mentioned earlier, the voltage V_{CC} at the voltage output 14 is determined by the initial voltage V_{AMP} and the offset voltage V_{OFF}. In this regard, it is possible to change the voltage V_{CC} by increasing or decreasing the offset voltage V_{OFF}, either in addition to or alternative to changing the initial voltage V_{AMP}. Specifically, to increase the offset voltage V_{OFF}, the control circuit 24 may close the bypass switch S_{BYP} such that the low-frequency current I_{DC} can charge the offset capacitor C_{OFF} to the offset voltage V_{OFF}. To decrease the offset voltage V_{OFF}, the control circuit 24 can lower the low-frequency voltage V_{DC} such that the offset capacitor C_{OFF} can be discharged through the power inductor L_{P} to decrease the offset voltage V_{OFF}.

In an embodiment, the voltage amplifier 28 may also source or sink a high-frequency current I_{AC} (e.g., an alternating current) to help speed up charging or discharging of the offset capacitor C_{OFF}. Accordingly, the voltage amplifier 28 is configured to generate a sense current I_{SENSE} to indicate an amount of the high-frequency current I_{AC} that is sourced or sunk by the voltage amplifier 28. As described below, the sense current I_{SENSE} can be utilized to determine the duty cycle signal 42 to help provide a desired amount of the low-frequency current I_{DC}.

In an embodiment, the control circuit 24 is configured to receive the feedback V_{CC}-FB of the voltage V_{CC}, the initial voltage V_{AMP}, and the sense current I_{SENSE}. Accordingly, the control circuit 24 can determine the amplifier target voltage V_{TGT-AMP}, the supply target voltage V_{TGT-SUP}, and the duty cycle signal 42 to thereby cause the voltage processing circuit 22 to transition the voltage V_{CC} from the present level V_{CC(N-1)} to the future level V_{CC(N)} within the defined voltage transition interval.

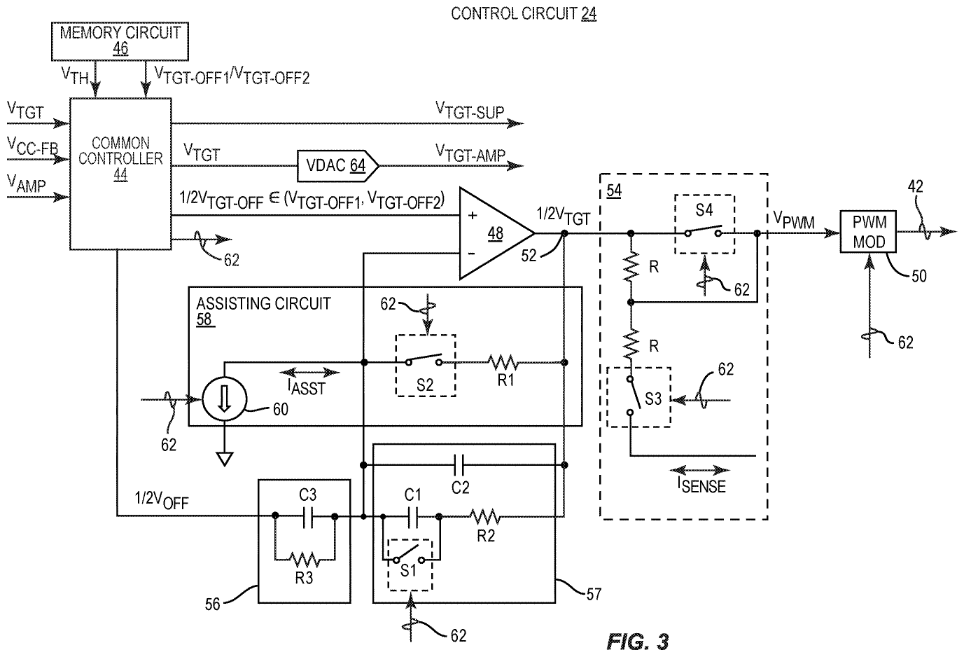

FIG. 3 is a schematic diagram providing an exemplary illustration of the control circuit 24 in FIG. 1. Common elements between FIGS. 1 and 3 are shown therein with common element numbers and will not be re-described herein.

Herein, the control circuit 24 includes a common controller 44 (e.g., a microprocessor, a microcontroller, etc.), a memory circuit 46 (e.g., a flash memory, a register bank, etc.), an operational amplifier 48, and a pulse-width modulation (PWM) modulator 50. The common controller 44 can be configured to receive the target voltage V_{TGT} from the transceiver circuit 20 in FIG. 1. The common controller 44 can be further configured to receive the feedback V_{CC-FB} of the voltage V_{CC} and the feedback of the initial voltage V_{AMP}. Accordingly, the common controller 44 can determine whether to employ the first voltage transition scheme or the second voltage transition scheme in accordance with the process 100 of FIG. 2.

The operational amplifier 48 includes a non-inverted input terminal (denoted as “+”), an inverted input terminal (denoted as “−”), and an output terminal 52. The output terminal 52 may be coupled to the PWM modulator 50, either directly or via a voltage divider circuit 54. As further discussed below, the operational amplifier 48 outputs one-half of the target voltage V_{TGT} (denoted as “½V_{TGT}”), which indicates the future level V_{CC(N)} of the voltage V_{CC} in the upcoming time interval S_{N}, to the PWM modulator 50 to thereby change the duty cycle signal 42 generated by the PWM modulator 50.

The common controller 44 may be coupled directly to the non-inverted input terminal (“+”), and to the inverted input terminal (“−”) of the operational amplifier 48 via an input circuit 56. The input circuit 56 includes a capacitor C3 and a resistor R3 coupled in parallel to each other. In addition, the control circuit 24 also includes a feedback circuit 57 coupled between the inverted terminal (“−”) and the output terminal 52. The feedback circuit 57 may include a capacitor C1 and a resistor R2 coupled in series between the inverted terminal (“−”) and the output terminal 52 of the operational amplifier 48 and a capacitor C2 coupled between the inverted terminal (“−”) and the output terminal 52, in parallel to the capacitor C1 and the resistor R2. The control circuit 24 may also include a switch S1 coupled in parallel to the capacitor C1. Understandably, when the switch S1 is closed, the capacitor C1 is bypassed.

In an embodiment, the control circuit 24 further includes an assisting circuit 58. The assisting circuit 58 includes a current source 60 coupled in series with a switch S2 and a resistor R1. The switch S2 and the resistor R1 are coupled between the inverted terminal (“−”) and the output terminal 52 of the operational amplifier 48, in parallel to the feedback circuit 57. The assisting circuit 58 can be activated by closing the switch S2 and deactivated by opening the switch S2. When the assisting circuit 58 is activated, the current source 60 can cause an assistance current I_{ASST} to flow through the resistor R1 to thereby accelerate a change (increase or decrease) of the target voltage ½V_{TGT} outputted by the operational amplifier 48.

The voltage divider circuit 54 can be controlled via switches S3, S4. Specifically, the switch S3 can be closed to couple the sense current I_{SENSE} through the voltage divider circuit 54 or opened to decouple the sense current I_{SENSE} from the voltage divider circuit 54. In an embodiment, the common controller 44 may control the PWM modulator 50, the current source 60, and the switches S1, S2, S3, S4, either individually or collectively, via at least one control signal 62. In this regard, the common controller 44 can activate or deactivate the assisting circuit 58 via the control signal 62.

The memory circuit 46 may be preconfigured to store, among others, the threshold voltage V_{TH} and a set of offset target voltages V_{TGT-OFF1}, V_{TGT-OFF2}. In a non-limiting example, the offset target voltages V_{TGT-OFF1}, V_{TGT-OFF2} can be expressed by equations (Eq. 1.1 and 1.2) below.

$${V}_{TGT - OFF 1} = {V}_{CC - MIN} - {V}_{NHEAD} \qquad ( Eq . 1.1 )$$

$${V}_{TGT - OFF 2} = {V}_{TH} - {V}_{NHEAD} \qquad ( Eq . 1.2 )$$

In the equations (Eq. 1.1 and 1.2), V_{CC-MIN} represents a minimum level of the voltage V_{CC} across the present time interval S_{N-1} and the upcoming time interval S_{N}, V_{TH} represents the threshold voltage, and V_{NHEAD} represents a headroom voltage. Herein, the common controller 44 is configured to determine an offset target voltage V_{TGT-OFF} for the upcoming time interval S_{N} by selecting one of the offset target voltages V_{TGT-OFF1}, V_{TGT-OFF2} from the memory circuit 46 (V_{TGT-OFF} ∈(V_{TGT-OFF1}, V_{TGT-OFF2})). Understandably, by selecting an appropriate one of the offset target voltages V_{TGT-OFF1}, V_{TGT-OFF2}, the control circuit 24 can determine the duty cycle signal 42 to thereby cause the switcher circuit 32 to generate the low-frequency current I_{DC} at the desired level. According to an embodiment of the present disclosure, the common controller 44 can select V_{TGT-OFF1} as the offset target voltage V_{TGT-OFF} (V_{TGT-OFF}=V_{TGT-OFF1}) when the future level V_{CC(N)} of the voltage V_{CC} in the upcoming time interval S_{N} is lower than the threshold voltage V_{TH} (V_{CC(N)}<V_{TH}). In contrast, when the future level V_{CC(N)} of the voltage V_{CC} in the upcoming time interval S_{N} is higher than or equal to the threshold voltage V_{TH} (V_{CC}(N)>V_{TH}), the common controller 44 can select V_{TGT-OFF2} as the offset target voltage V_{TGT-OFF} (V_{TGT-OFF}=V_{TGT-OFF2}).

Upon selecting the offset target voltage V_{TGT-OFF} among the offset target voltages V_{TGT-OFF1}, V_{TGT-OFF2}, the common controller 44 is configured to provide one-half of the selected offset target voltage V_{TGT-OFF} (denoted as “½V_{TGT-OF}F”) to the non-inverted terminal (“+”) of the operational amplifier 48.

The common controller 44 also determines the offset voltage V_{OFF} in the present time interval S_{N-1} based on the feedback V_{CC-FB} of the voltage V_{CC} and the feedback of the initial voltage V_{AMP} in the present time interval S_{N-1} (V_{OFF}=V_{CC-FB}−V_{AMP}). Accordingly, the common controller 44 provides one-half of the offset voltage V_{OFF} in the present time interval S_{N-1} (denoted as “½V_{OFF}”) to the inverted terminal “−” of the operational amplifier 48 via the input circuit 56. The operational amplifier 48, in turn, outputs the target voltage ½V_{TGT} to indicate the future level V_{CC(N)} of the voltage V_{CC} in the upcoming time interval S_{N}.

As mentioned earlier in FIG. 1, the voltage amplifier 28 may source or sink the high-frequency current I_{AC} to help speed up charging or discharging of the offset capacitor C_{OFF}. Understanding that the voltage amplifier 28 may suffer a reduced efficiency when sourcing or sinking the high-frequency current I_{AC}, it is thus desirable to reduce the high-frequency current I_{AC} to help improve the efficiency of the voltage amplifier 28.

In this regard, the control circuit 24 is further configured to adapt the duty cycle signal 42 in accordance with the high-frequency current I_{AC} being sourced or sunk by the voltage amplifier 28. More specifically, during transition of the voltage V_{CC}, the common controller 44 can close the switch S3 and open the switch S4 to couple the sense current I_{SENSE}, which serves as an indication of the high-frequency current I_{AC}, into the voltage divider circuit 54 to thereby establish a PWM target voltage V_{PWM}. Accordingly, the PWM modulator 50 can generate the duty cycle signal 42 based on the PWM target voltage V_{PWM}. As a result, it is possible to increase or decrease the low-frequency current I_{DC} to compensate for the high-frequency current I_{AC} being sourced or sunk by the voltage amplifier 28 to thereby improve efficiency of the voltage amplifier 28. Accordingly, the PWM target voltage V_{PWM} as received by the PWM modulator 50 can be expressed in equation (Eq. 2.1) below. In contrast, outside the transition of the voltage V_{CC}, the common controller 44 can close the switch S4 and open the switch S3 to thereby cause the PWM target voltage V_{PWM} to be generated in accordance with equation (Eq. 2.2) below.

$${V}_{PWM} = 1 / 2 {V}_{T G T} \pm {I}_{SENSE} \times 2 R \qquad ( Eq . 2.1 )$$

$${V}_{PWM} = 1 / 2 {V}_{T G T} \qquad ( Eq . 2.2 )$$

In an embodiment, in the first voltage transition scheme, the common controller 44 is configured to activate the assisting circuit 58 at a start of the upcoming time interval S_{N} and deactivate the assisting circuit 58 at an end of the defined voltage transition interval. As mentioned earlier, the defined voltage transition interval can be a shorter one of 2 μs and the duration of the CP in the upcoming time interval S_{N}. Herein, the common controller 44 can further control the current source 60 to adapt the assistance current I_{ASST} to accelerate the transition (increase or decrease) of the offset voltage V_{OFF}, such that the PMIC 12 in FIG. 1 can change the voltage V_{CC} within the defined voltage transition interval.

In one example, if the defined voltage transition interval is 2 μs, the common controller 44 may control the current source 60 to generate the assistance current I_{ASST} as expressed in equation (Eq. 3) below.

$${I}_{ASST} = ( 1 / 2 {V}_{TGT} - 1 / 2 {V}_{OFF} ) / R 1 \qquad ( Eq . 3 )$$

In another example, if the defined voltage transition interval is far less than 2 μs (e.g., 0.59 μs associated with 120 KHz SCS), the common controller 44 may control the current source 60 to increase the assistance current I_{ASST} as expressed in equation (Eq. 4) below.

$${I}_{ASST} = ( 1 / 2 {V}_{TGT} - 1 / 2 {V}_{OFF} ) / R 1 + ( 1 / 2 {V}_{TGT} - 1 / 2 {V}_{CC ( N - 1 )} ) / R 2 \qquad ( Eq . 4 )$$

The common controller 44 may close the switch S1 to bypass the capacitor C1 when V_{TGT} is less than one volt (V_{TGT}<1V). The common controller 44 may also close the switch S1 to bypass the capacitor C1 to cause the target voltage ½V_{TGT} at the output terminal 52 to decrease quickly under the follow condition:

$${V}_{CC ( N - 1 )} - {V}_{CC ( N )} > 2.5 V and {V}_{TGT} < ( {V}_{OFF} + 0.6 V )$$

In an embodiment, the common controller 44 may also increase an operating frequency of the PWM modulator 50 such that the PWM modulator 50 can make a timely decision as to how the duty cycle signal 42 should be generated. The common controller 44 is further configured to provide the target voltage V_{TGT} to a voltage digital-to-analog converter (VDAC) 64, which will generate the amplifier target voltage V_{TGT-AMP}.

The common controller 44 is further configured to generate the supply target voltage V_{TGT-SUP} to adapt the supply voltage V_{SUP}. For example, the common controller 44 can decrease the supply target voltage V_{TGT-SUP} to reduce the supply voltage V_{SUP} when the future level V_{CC(N)} of the voltage V_{CC} is lower than the present level V_{CC(N-1)} of the voltage V_{CC}. The common controller 44 can increase the supply target voltage V_{TGT-SUP} to increase the supply voltage V_{SUP} when the future level V_{CC(N)} of the voltage V_{CC} is higher than the present level V_{CC(N-1)} of the voltage V_{CC}. The common controller 44 can maintain the supply target voltage V_{TGT-SUP} at the previous level to keep the supply voltage V_{SUP} unchanged when the future level V_{CC(N)} of the voltage V_{CC} is equal to the present level V_{CC(N-1)} of the voltage V_{CC}. By adapting the supply voltage V_{SUP} based on the present level V_{CC(N-1)} and the future level V_{CC(N)} of the voltage V_{CC}, it is possible to improve efficiency and reduce energy waste of the voltage amplifier 28.

Should the control circuit 24 determine, based on the process 100 of FIG. 2, that the PMIC 12 will adapt the voltage V_{CC} based on the second voltage transition scheme, the control circuit 24 can cause the PMIC 12 to change the voltage V_{CC} from the present level V_{CC(N-1)} to the future level V_{CC(N)} by modulating the offset voltage V_{OFF} and/or changing only the initial voltage V_{AMP}.

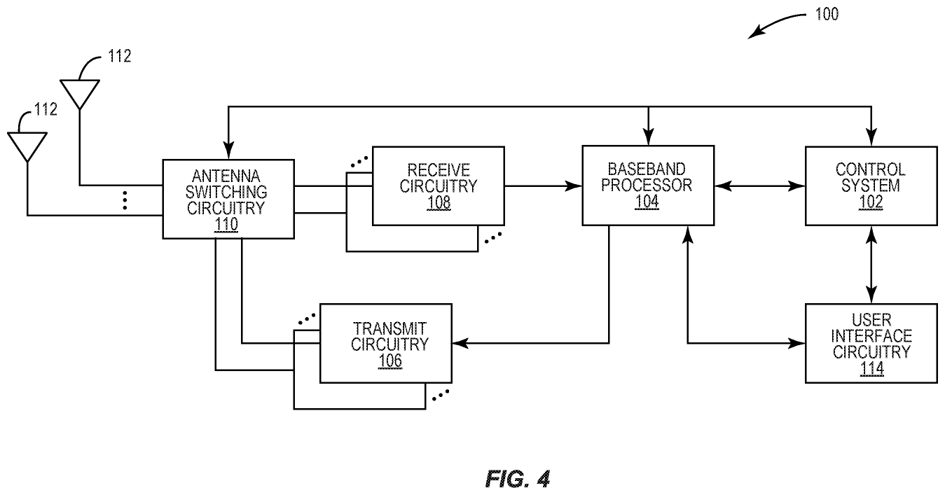

The wireless transmission circuit 10 of FIG. 1 can be provided in a communication device to support the embodiments described above. In this regard, FIG. 4 is a schematic diagram of an exemplary communication device 100 wherein the wireless transmission circuit 10 of FIG. 1 can be provided.

Herein, the communication device 100 can be any type of communication device, such as a mobile terminal, smart watch, tablet, computer, navigation device, access point, base station (e.g., eNB, gNB), and any wireless communication device that supports wireless communications, such as cellular, wireless local area network (WLAN), Bluetooth, Ultra-wideband (UWB), and near field communications. The communication device 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

In one embodiment, the PMIC 12 may be provided in the antenna switching circuitry 110 and coupled to the transmit circuitry 106 and/or the receive circuitry 108. In another embodiment, the PMIC 12 may be a separate circuit provided in between the transmit circuitry 106 and the antenna switching circuitry 110. Notably, the PMIC 12 may also be provided in any other circuits in the communication device 100.

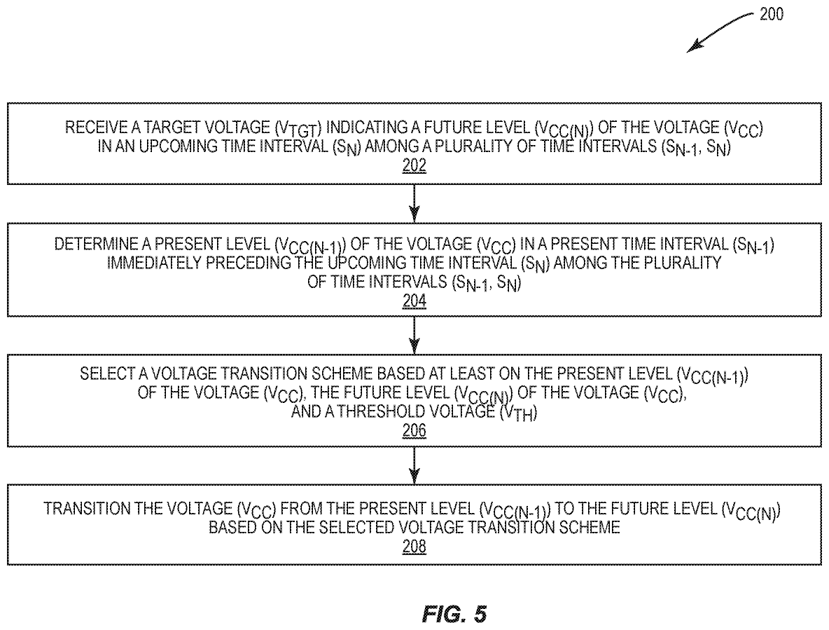

In an embodiment, it is possible to switch the voltage V_{CC} in the PMIC 12 based on a process. In this regard, FIG. 5 is a flowchart of an exemplary process 200 for switching the voltage V_{CC} in the PMIC 12 in FIG. 1.

Herein, the process 200 includes receiving the target voltage V_{TGT} indicating the future level V_{CC(N)} of the voltage V_{CC} in the upcoming time interval S_{N} among the time intervals S_{N-1}, S_{N} (step 202). The process 200 also includes determining the present level V_{CC(N-1)} of the voltage V_{CC} in the present time interval S_{N-1} immediately preceding the upcoming time interval S_{N} among the time intervals S_{N-1}, S_{N} (step 204). The process 200 also includes selecting the voltage transition scheme based at least on the present level V_{CC(N-1)} of the voltage V_{CC}, the future level V_{CC(N)} of the voltage V_{CC}, and the threshold voltage V_{TH} (step 206). The process 200 also includes transitioning the voltage V_{CC} from the present level V_{CC(N-1)} to the future level V_{CC(N)} based on the selected voltage transition scheme (step 208).

Those skilled in the art will recognize improvements and modifications to the preferred embodiments of the present disclosure. All such improvements and modifications are considered within the scope of the concepts disclosed herein and the claims that follow.

1. A power management integrated circuit (PMIC) comprising:
a voltage processing circuit configured to generate a voltage in each of a plurality of time intervals for amplifying a radio frequency (RF) signal; and
a control circuit configured to:
receive a target voltage indicating a future level of the voltage in an upcoming time interval among the plurality of time intervals;
determine a present level of the voltage in a present time interval immediately preceding the upcoming time interval among the plurality of time intervals;
select a voltage transition scheme based at least on the present level of the voltage, the future level of the voltage, and a threshold voltage; and
control the voltage processing circuit to transition the voltage from the present level to the future level based on the selected voltage transition scheme.

2. The PMIC of claim 1, wherein the control circuit is further configured to:
control the voltage processing circuit based on a first voltage transition scheme under any of following conditions:
the present level and the future level of the voltage are both higher than or equal to the threshold voltage; and
the present level and the future level of the voltage are both lower than the threshold voltage; and
control the voltage processing circuit based on a second voltage transition scheme under any following conditions:
the present level of the voltage is higher than or equal to the threshold voltage and the future level of the voltage is lower than the threshold voltage; and
the present level of the voltage is lower than the threshold voltage and the future level of the voltage is higher than or equal to the threshold voltage.

3. The PMIC of claim 2, wherein the voltage processing circuit comprises:
a voltage amplifier configured to generate an initial voltage based on a supply voltage and an amplifier target voltage;
an offset circuit configured to raise the initial voltage by an offset voltage to generate the voltage;
a switcher circuit configured to generate a low-frequency current based on a duty cycle signal to thereby cause the offset circuit to provide the offset voltage; and
a supply voltage circuit configured to generate the supply voltage based on a supply target voltage.

4. The PMIC of claim 3, wherein the control circuit is further configured to:
cause the offset circuit to keep the offset voltage constant under the first voltage transition scheme; and
cause the offset circuit to modulate the offset voltage under the second voltage transition scheme.

5. The PMIC of claim 3, wherein the control circuit comprises:
a pulse-width modulation (PWM) modulator configured to generate the duty cycle signal based on a PWM target voltage that is related to one-half of the target voltage;
an operational amplifier configured to output the one-half of the future level of the voltage based on one-half of an offset target voltage in the upcoming time interval and one-half of the offset voltage in the present time interval; and
a common controller configured to:
determine the one-half of the offset target voltage in the upcoming time interval based on the present level of the voltage, the future level of the voltage, and the threshold voltage; and
determine the one-half of the offset voltage in the present time interval based on feedback of the voltage and the initial voltage.

6. The PMIC of claim 5, wherein the common controller is further configured to:
determine the offset target voltage to be equal to (V_{CC-MIN}−V_{NHEAD}) when the future level of the voltage is lower than the threshold voltage; and
determine the offset target voltage to be equal to (V_{TH}−V_{NHEAD}) when the future level of the voltage is higher than or equal to the threshold voltage;
wherein V_{CC-MIN} represents a minimum level of the voltage; V_{NHEAD} represents a headroom voltage; and V_{TH} represents the threshold voltage.

7. The PMIC of claim 5, wherein the control circuit further comprises an assisting circuit and the common controller is further configured to activate the assisting circuit in one or more of the first voltage transition scheme and the second voltage transition scheme to cause the operational amplifier to output the one-half of the future level of the voltage within a defined voltage transition interval.

8. The PMIC of claim 7, wherein the common controller is further configured to deactivate the assisting circuit at an end of the defined voltage transition interval.

9. The PMIC of claim 7, wherein the common controller is further configured to:
increase the supply target voltage when the future level of the voltage is higher than the present level of the voltage;
decrease the supply target voltage when the future level of the voltage is lower than the present level of the voltage; and
maintain the supply target voltage when the future level of the voltage is equal to the present level of the voltage.

10. The PMIC of claim 1, wherein each of the plurality of time intervals has a duration of an orthogonal frequency division multiplexing (OFDM) symbol.

11. A method for switching a voltage in a power management integrated circuit (PMIC) comprising:
receiving a target voltage indicating a future level of the voltage in an upcoming time interval among a plurality of time intervals;
determining a present level of the voltage in a present time interval immediately preceding the upcoming time interval among the plurality of time intervals;
selecting a voltage transition scheme based at least on the present level of the voltage, the future level of the voltage, and a threshold voltage; and
transitioning the voltage from the present level to the future level based on the selected voltage transition scheme.

12. The method of claim 11, wherein selecting the voltage transition scheme comprises:
selecting a first voltage transition scheme under any following conditions:
the present level and the future level of the voltage are both higher than or equal to the threshold voltage; and
the present level and the future level of the voltage are both lower than the threshold voltage; and
selecting a second voltage transition scheme under any following conditions:
the present level of the voltage is higher than or equal to the threshold voltage and the future level of the voltage is lower than the threshold voltage; and
the present level of the voltage is lower than the threshold voltage and the future level of the voltage is higher than or equal to the threshold voltage.

13. A wireless device comprising a power management integrated circuit (PMIC) comprising:
a voltage processing circuit configured to generate a voltage in each of a plurality of time intervals for amplifying a radio frequency (RF) signal; and
a control circuit configured to:
receive a target voltage indicating a future level of the voltage in an upcoming time interval among the plurality of time intervals;
determine a present level of the voltage in a present time interval immediately preceding the upcoming time interval among the plurality of time intervals;
select a voltage transition scheme based at least on the present level of the voltage, the future level of the voltage, and a threshold voltage; and
control the voltage processing circuit to transition the voltage from the present level to the future level based on the selected voltage transition scheme.

14. The wireless device of claim 13, wherein the control circuit is further configured to:
control the voltage processing circuit based on a first voltage transition scheme under any following conditions:
the present level and the future level of the voltage are both higher than or equal to the threshold voltage; and
the present level and the future level of the voltage are both lower than the threshold voltage; and
control the voltage processing circuit based on a second voltage transition scheme under any following conditions:
the present level of the voltage is higher than or equal to the threshold voltage and the future level of the voltage is lower than the threshold voltage; and
the present level of the voltage is lower than the threshold voltage and the future level of the voltage is higher than or equal to the threshold voltage.

15. The wireless device of claim 14, wherein the voltage processing circuit comprises:
a voltage amplifier configured to generate an initial voltage based on a supply voltage and an amplifier target voltage;
an offset circuit configured to raise the initial voltage by an offset voltage to generate the voltage;
a switcher circuit configured to generate a low-frequency current based on a duty cycle signal to thereby cause the offset circuit to provide the offset voltage; and
a supply voltage circuit configured to generate the supply voltage based on a supply target voltage.

16. The wireless device of claim 15, wherein the control circuit is further configured to:
cause the offset circuit to keep the offset voltage constant under the first voltage transition scheme; and
cause the offset circuit to modulate the offset voltage under the second voltage transition scheme.

17. The wireless device of claim 15, wherein the control circuit comprises:
a pulse-width modulation (PWM) modulator configured to generate the duty cycle signal based on a PWM target voltage that is related to one-half of the target voltage;
an operational amplifier configured to output the one-half of the future level of the voltage based on one-half of an offset target voltage in the upcoming time interval and one-half of the offset voltage in the present time interval; and
a common controller configured to:
determine the one-half of the offset target voltage in the upcoming time interval based on the present level of the voltage, the future level of the voltage, and the threshold voltage; and
determine the one-half of the offset voltage in the present time interval based on feedback of the voltage and the initial voltage.

18. The wireless device of claim 17, wherein the common controller is further configured to:
determine the offset target voltage to be equal to (V_{CC-MIN}−V_{NHEAD}) when the future level of the voltage is lower than the threshold voltage; and
determine the offset target voltage to be equal to (V_{TH}−V_{NHEAD}) when the future level of the voltage is higher than or equal to the threshold voltage;
wherein V_{CC-MIN} represents a minimum level of the voltage; V_{NHEAD} represents a headroom voltage; and V_{TH} represents the threshold voltage.

19. The wireless device of claim 17, wherein the control circuit further comprises an assisting circuit and the common controller is further configured to activate the assisting circuit in one or more of the first voltage transition scheme and the second voltage transition scheme to cause the operational amplifier to output the one-half of the future level of the voltage within a defined voltage transition interval.

20. The wireless device of claim 19, wherein the common controller is further configured to deactivate the assisting circuit at an end of the defined voltage transition interval.
